(19) United States
(12) Patent Application Publication
(10) Pub. No.: US 2018/0047885 A1
(43) Pub. Date: Feb. 15, 2018

(54) MULTI-MATERIAL LED HEAT SINKS

(71) Applicant: GM Global Technology Operations LLC, Detroit, MI (US)

(72) Inventors: DAVID C. HELLMAN, WARREN, MI (US); SHANNEN M. BORNGESSER, WARREN, MI (US); MICHAEL K. LARSEN, WARREN, MI (US); JAMES C. O'KANE, WARREN, MI (US)

(21) Appl. No.: 15/232,893

(22) Filed: Aug. 10, 2016

(51) Int. Cl. H01L 33/64

(52) U.S. Cl. CPC H01L 33/641; H01L 2933/0075

(57) ABSTRACT

A number of variations may include a product that may include a first heat sink that may include a first face opposite a second face, a plurality of fins disposed on the second face, and a recess that may be defined by the first face; a second heat sink may be disposed within the recess and may have a third face opposite a fourth face wherein the fourth face may be disposed within the recess; and a light-emitting diode may be disposed on the fourth face of the second heat sink.

### TECHNICAL FIELD

The field to which the disclosure generally relates includes heat sinks.

### BACKGROUND

Low cost, low mass light-emitting diodes (LED) may utilize small package heat sinks.

### SUMMARY OF ILLUSTRATIVE VARIATIONS

A number of variations may include a product that may include a first heat sink that may include a first face opposite a second face, a plurality of fins disposed on the second face, and a recess that may be defined by the first face; a second heat sink may be disposed within the recess and may have a third face opposite a fourth face wherein the fourth face may be disposed within the recess; and a light-emitting diode may be disposed on the fourth face of the second heat sink.

A number of variations may include a method that may include providing a first heat sink that may include a first face opposite a second face, a plurality of fins that may be disposed on the second face, and a recess may be defined by the first face; providing a second heat sink; disposing the second heat sink within the recess; and disposing a light-emitting diode on the second heat sink.

A number of variations may include a method that may include providing a second heat sink; forming a first heat sink around the second heat sink wherein the first heat sink may include a first face opposite a second face, a plurality of fins may be disposed on the second face, and a recess may be defined by the first face wherein the second heat sink resides within the recess: and disposing a light-emitting diode on the second heat sink.

Other illustrative variations within the scope of the invention will become apparent from the detailed description provided hereinafter. It should be understood that the detailed description and enumerated variations, while disclosing optional variations, are intended for purposes of illustration only and are not intended to limit the scope of the invention.

### BRIEF DESCRIPTION OF THE DRAWINGS

Select examples of variations within the scope of the invention will become more fully understood from the detailed description and the accompanying drawings, wherein:

FIG. 1 depicts one variation of a multi-material LED heat sink; and

FIG. 2 depicts a cross-sectional view of one variation of a multi-material LED heat sink.

### DETAILED DESCRIPTION OF ILLUSTRATIVE VARIATIONS

The following description of the variations is merely illustrative in nature and is in no way intended to limit the scope of the invention, its application, or uses. The following description of variants is only illustrative of components, elements, acts, products, and methods considered to be within the scope of the invention and are not in any way intended to limit such scope by what is specifically disclosed or not expressly set forth. The components, elements, acts, products, and methods as described herein may be combined and rearranged other than as expressly described herein and still are considered to be within the scope of the invention.

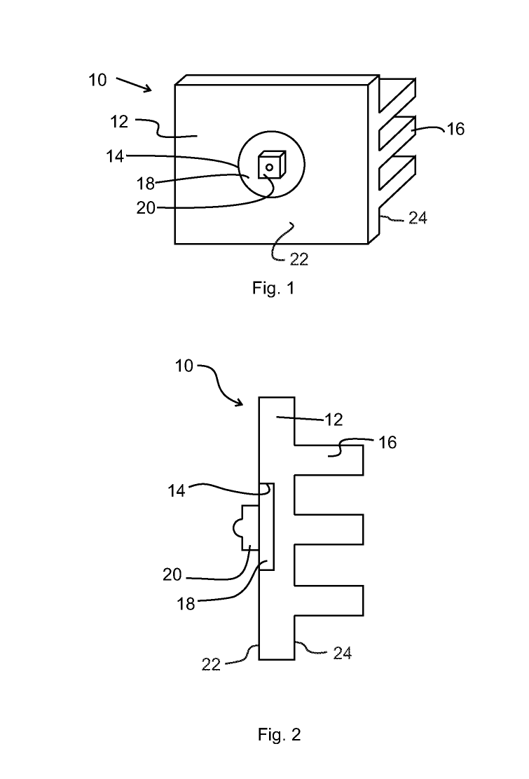

Referring to FIGS. 1 and 2; an LED assembly 10 may include a first heat sink 12 that may include a thermally conductive polymer which may include a first surface 22 opposite a second surface 24 wherein the first surface 22 may define a recess 14 and the second surface may include a plurality of fins 16. The LED assembly 10 may further include a second heatsink 18 that may include a thermally conductive metal such as, but not limited to, copper. An LED 20 may be disposed on the second heat sink 18.

As best seen in FIG. 2; the first heat sink 12 may define a recess 14 in its first face 22 and a second heat sink 18 may be disposed or nested within the recess 14. The first heat sink 16 and second heat sink 18 may be constructed and arranged to draw heat away from the LED 20 which may be disposed on the second heat sink 18.

A method of producing an LED assembly 10 may include providing a first heat sink 12 and subsequently molding a second heat sink 18 around the first heat sink 12 leaving at least one surface of the first heat sink 12 exposed. An LED 20 may be subsequently added to the at least one surface of the first heat sink 12.

According to variation 1, a product may include a first heat sink that may include a first face opposite a second face, a plurality of fins disposed on the second face, and a recess that may be defined by the first face; a second heat sink may be disposed within the recess and may have a third face opposite a fourth face wherein the fourth face may be disposed within the recess; and a light-emitting diode may be disposed on the fourth face of the second heat sink.

Variation 2 may include a product as set forth in variation 1 wherein the first heat sink may include a polymeric material.

Variation 3 may include a product as set forth in variation 1 or 2 wherein the second heat sink may include a metallic material.

Variation 4 may include a product as set forth in any of variations 1 through 3 wherein the metallic material may be copper.

According to variation 5, a method may include providing a first heat sink that may include a first face opposite a second face, a plurality of fins that may be disposed on the second face, and a recess may be defined by the first face; providing a second heat sink; disposing the second heat sink within the recess; and disposing a light-emitting diode on the second heat sink.

Variation 6 may include a product as set forth in variation 5 wherein the first heat sink may include a polymeric material.

Variation 7 may include a product as set forth in any of variations 5 through 6 wherein the second heat sink may include a metallic material.

Variation 8 may include a product as set forth in any of variations 5 through 7 wherein the metallic material may be copper.

According to variation 9, a method may include providing a second heat sink; forming a first heat sink around the second heat sink wherein the first heat sink may include a first face opposite a second face, a plurality of fins may be disposed on the second face, and a recess may be defined by the first face wherein the second heat sink resides within the recess: and disposing a light-emitting diode on the second heat sink.

Variation 10 may include a product as set forth in variation 9 wherein the first heat sink may include a polymeric material.

Variation 11 may include a product as set forth in any of variations 9 and 10 wherein the second heat sink may include a metallic material.

Variation 12 may include a product as set forth in any of variations 1 through 11 wherein the metallic material may be copper.

The above description of variations of the invention is merely demonstrative in nature and, thus, variations thereof are not to be regarded as a departure from the spirit and scope of the inventions disclosed within this document.

1. A product comprising:
a first heat sink comprising a first face opposite a second face, a plurality of fins disposed on the second face, and a recess defined by the first face;
a second heat sink disposed within the recess having a third face opposite a fourth face wherein the fourth face is disposed within the recess; and
a light-emitting diode disposed on the fourth face of the second heat sink.

2. A product as set forth in claim 1, wherein the first heat sink comprises a polymeric material.

3. A product as set forth in claim 1, wherein the second heat sink comprises a metallic material.

4. A product as set forth in claim 3, wherein the metallic material is copper.

5. A method comprising:
providing a first heat sink comprising a first face opposite a second face, a plurality of fins disposed on the second face, and a recess defined by the first face;
providing a second heat sink;
disposing the second heat sink within the recess; and
disposing a light-emitting diode on the second heat sink.

6. A method as set forth in claim 5, wherein the first heat sink comprises a polymeric material.

7. A method as set forth in claim 5, wherein the second heat sink comprises a metallic material.

8. A method as set forth in claim 7, wherein the metallic material is copper.

9. A method comprising:
providing a second heat sink;
forming a first heat sink around the second heat sink wherein the first heat sink comprises a first face opposite a second face, a plurality of fins disposed on the second face, and a recess defined by the first face wherein the second heat sink resides within the recess: and
disposing a light-emitting diode on the second heat sink.

10. A method as set forth in claim 9, wherein the first heat sink comprises a polymeric material.

11. A method as set forth in claim 9, wherein the second heat sink comprises a metallic material.

12. A method as set forth in claim 11, wherein the metallic material is copper.
